(19) United States
(12) Patent Application Publication
(10) Pub. No.: US 2009/0291323 A1
(43) Pub. Date: Nov. 26, 2009

(54) DISPERSION STRENGTHENED CERAMIC THERMAL BARRIER COATING

(75) Inventors: Kevin W. Schlichting, Storrs, CT (US); Paul H. Zajchowski, Enfield, CT (US)

Correspondence Address: KINNEY & LANGE, P.A., THE KINNEY & LANGE BUILDING, 312 SOUTH THIRD STREET, MINNEAPOLIS, MN, 55415-1002, US

(73) Assignee: UNITED TECHNOLOGIES CORPORATION, Hartford, CT (US)

(21) Appl. No.: 12/126,498

(22) Filed: May 23, 2008

(51) Int. Cl. B05D 1/36; H05H 1/24; B32B 5/16; C23C 16/40

(52) U.S. Cl. 428/698; 427/419.7; 427/577; 428/688; 428/328; 106/287.19; 106/287.18

(57) ABSTRACT

A method of forming a thermal barrier coating on a turbine component is disclosed. The method comprises first depositing a bond coat on the turbine component. A dispersion strengthened ceramic layer containing boride particles as dispersoids is formed on the bond coat layer by plasma deposition. Ceramic coated boride particles comprise the plasma deposition feedstock in order to disperse the boride particles in the ceramic layer. The dispersion strengthened ceramic layer includes at least one of yttria-stabilized zirconia, rare earth stabilized zirconia, rare earth stabilized hafnia, and rare earth stabilized titanate.

### BACKGROUND

The present invention relates to thermal barrier coatings. In particular, the invention relates to dispersion strengthened ceramic thermal barrier coatings with improved fracture toughness.

The efficiency of a gas turbine engine scales as the difference between the inlet temperature and outlet temperature of the working fluid, typically a mixture of air and fuel in modern aeromachine engines. Working temperatures are steadily increasing, as are the development of base alloys and protective coating systems to withstand the increasingly demanding environment in the gas flow path. Embodiments of a modern, high temperature turbine component typically consists of four parts. The first part is the base alloy which is typically either a nickel base or cobalt base superalloy. The second part is typically an aluminum-containing protective bond coat overlay on the base alloy. Bond coats of choice are nickel aluminides, platinum-modified nickel aluminides, and MCrAlX alloys where M is iron (Fe), nickel (Ni), and/or cobalt (Co), and X is yttrium (Y), silicon (Si), hafnium (Hf), a rare earth, or mixtures thereof. The next part of the multi-layer structure is typically an aluminum oxide protective layer that forms on the bond coat and thickens with elevated temperature operation. The last part is typically a thermally insulating ceramic topcoat deposited on the bond coat that offers mechanical resistance as well as thermal resistance to the hot gas path. A popular topcoat of choice is zirconia stabilized with 7 weight percent yttria. The bond coat, aluminum oxide layer and ceramic topcoat form a thermal barrier coating (TBC) that allows increased working temperatures and the resulting efficiencies experienced in modern gas turbine engines. The lifetime of the TBC dictates the lifetime of the turbine engine. TBC's fail by two predominant mechanisms: abrasive wear and spalling. Abrasive wear results from particle impact from the working fluid. Spalling is attributed to excessive oxide layer growth at the bond coat/topcoat interface as well as thermal fatigue due to cyclic thermal expansion and contraction during the duty cycle. Both failure mechanisms are directly related to the fracture toughness of the ceramic topcoat. Ceramic topcoats with improved fracture toughness would extend the turbomachine lifetime.

### SUMMARY

This invention provides a plasma sprayed ceramic thermal barrier coating on a turbine component with improved fracture toughness and spallation resistance. The coating is strengthened and toughened by a uniform dispersion of approximately 10 micron diameter boride particles. The boride particles are introduced in the ceramic microstructure during plasma deposition as a component of composite powder feedstock. The feedstock comprises ceramic coated boride particles. The boride particles may include one or more of: aluminum diboride, titanium diboride, zirconium diboride, hafnium diboride, lanthanum hexaboride, rhenium diboride, strontium diboride, and others. The ceramic coating may include one or more of: yttria stabilized zirconia, rare earth stabilized zirconia, rare earth stabilized hafnia and rare earth stabilized titanate.

### BRIEF DESCRIPTION OF THE DRAWINGS

FIG. 1 is a cross-sectional view of the microstructure of a composite powder particle.

FIG. 2 is a cross-sectional view of a thermal barrier coating in accordance with the present invention.

FIG. 3 is a schematic showing geometry of crack deflection due to particle interaction.

### DETAILED DESCRIPTION

Thermal barrier coatings (TBC) on high temperature turbine components consist of at least a metallic bond coat and a ceramic topcoat. The low thermal conductivity of the ceramic protects the component from the hot gases and extends the working temperature (and efficiency) of the turbomachine. Thermal barrier coating lifetimes are dependent on two failure mechanisms: abrasive wear and spalling. Both mechanisms are fracture dominated and are related to the fracture toughness of the ceramic. Increasing the fracture toughness of the ceramic topcoat will extend the lifetime of the TBC. One approach to increase the fracture toughness of a ceramic is to incorporate particles of a hard second phase in the structure. The particles increase the resistance to fracture by deflecting propagating cracks thereby increasing the energy for subsequent crack propagation. Dispersion strengthened thermal barrier coatings are taught by U.S. Publication No. 2006/0024513, Schlichting et al., U.S. Publication No. 2003/0138660, Darolia et al., U.S. Pat. No. 6,667,049, Darolia et al., and U.S. Pat. No. 6,436,480, Upadhya and are included by reference herein in their entirety.

Two general processes are used for depositing the ceramic topcoat in thermal barrier coatings: physical vapor deposition (PVD) and plasma spraying. PVD is sometimes assisted by chemical vapor deposition (CVD). A preferred PVD process to those versed in the art is electron beam physical vapor deposition (EBPVD). EBPVD generally consists of loading a component to be coated into a chamber, evacuating the chamber and backfilling with a suitable atmosphere. A component is placed in proximity of an ingot of the coating material, 7 weight percent yttria stabilized zirconia, for example. One or more electron beams focused on the ingot evaporate the ingot to produce a vapor of the coating material that condenses on the component to form a coating. Ceramic topcoats containing vertical columns for strain tolerance are produced in this manner. Plasma spraying, on the other hand, consists of projecting a stream of precursor powder particles through a plasma flame toward a component to be coated. As the particles pass through the plasma, their outer surfaces partially melt. When the partially molten particles impact the target, they deform into pancake shaped drops or “splats” and rapidly solidify. Plasma spraying can be carried out in air or any other suitable environment. This structure will be discussed in more detail below. Suitable candidate ceramic materials for the topcoat include rare earth stabilized zirconias, hafnias, and titanates. Suitable candidate materials for the reinforcing particles include carbides, borides, and nitrides. The zirconias, hafnias, and titanates are generally stable in a plasma environment and survive the spraying process. Carbides, borides, and nitrides on the other hand are not stable and are prone to rapid volitization in a plasma. As a result, carbides, borides, and nitrides cannot generally be used as raw feed stock in plasma spraying. An inventive composite ceramic particle containing a reinforcing boride particle as a plasma spray feed stock particle is a first embodiment of the present invention.

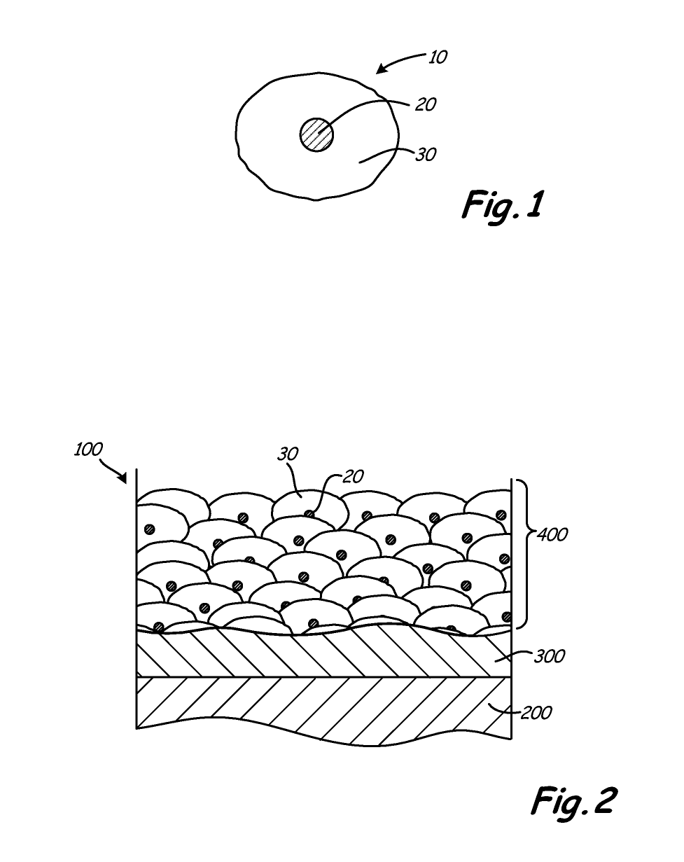

FIG. 1 shows a cross-sectional view of the microstructure of the inventive composite plasma spray feed stock composite particle 10. Composite particle 10 comprises reinforcing particle 20 surrounded by protective ceramic coating 30. Reinforcing particle 20 is desirably selected from the group comprising aluminum diboride, titanium diboride, zirconium diboride, hafnium diboride, lanthanum hexaboride, rhenium diboride, strontium diboride and others. The size of reinforcing particle 20 is about 2 microns (0.08 mils) to about 40 microns (1.6 mils), more desirably about 2 microns (0.08 mils) to about 25 microns (1 mil), and even more desirably about 8 microns (0.3 mils) to about 12 microns (0.5 mils).

Protective ceramic coating 30 is desirably selected from the group comprising yttria stabilized zirconia, rare earth stabilized zirconias, hafnias, and titanates. The diameter of composite particle 10 is about 10 microns (0.4 mils) to about 176 microns (7 mils) more desirably about 20 microns (0.8 mils) to about 90 microns (3.5 mils), and even more desirably about 55 microns (2.2 mils) to about 70 microns (2.8 mils).

Air plasma spray (APS), low pressure plasma spray (LPPS), and other methods known to those versed in the art can be used to deposit thermal barrier coatings discussed herein. MCrAlX bondcoats, where M is Fe, Ni and/or Co, and X is Y, Si, Hf, a rare earth or mixtures thereof, are commonly applied using LPPS and EBPVD. Nickel aluminide bondcoats are typically applied using pack cementation, vapor phase aluminiding or chemical vapor deposition (CVD). The ceramic topcoat of the present invention is preferably applied using APS or LPPS. A cross-section of the dispersion strengthened ceramic thermal barrier coating of the present invention is shown in FIG. 2. In the figure, thermal barrier coating 400 is disposed on bondcoat 300. Bondcoat 300 is on superalloy substrate 200. Ceramic topcoat 400 is applied by plasma spraying and the microstructure consists of flattened grains or “splats”. Significantly, a dispersion strengthening reinforcing particle 20 is situated in the center of each protective ceramic coating 30. The particles act to disrupt crack propagation by deflecting crack tips that encounter each particle.

The increase in fracture toughness due to particle reinforcement can be calculated using the rule of mixtures as given by:

K_{ICcomp}=fₚK_{ICp}+fₘK_{ICm}

where K_{ICcomp} is the fracture toughness of the composite, fₚ and fₘ are the volume fraction, and K_{ICp} and K_{ICm} are the fracture toughness of the particle and matrix respectively. Fracture toughness will be affected somewhat by the mole fraction of the reinforcing particles.

However, the increase in the fracture toughness of the composite depends more on the crack tip deflection by the hard reinforcing particle in the crack path than on the fracture toughness of each component. The propagation rate of a crack that is deflected from its straight growth direction requires a larger driving force than a corresponding straight crack of the same effective length. A deflected crack propagates at a slower rate compared to a straight crack at the same effective stress. In addition, as the crack is unloaded and closure occurs, mismatch can occur between the rough asperities of the crack mating phases. This added contact stress further amplifies the apparent driving force required to propagate a deflected crack at the same rate as a corresponding straight crack.

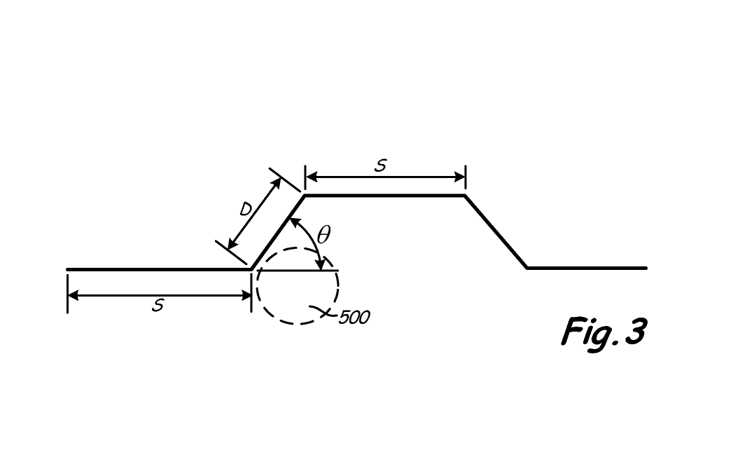

The apparent crack propagation rate for a Mode I crack that is periodically deflected along the projected Mode I plane by particle 500 as shown in FIG. 3 is given by:

da/dn={D*cos θ+(1−D*)}da/dn_{L} (1)

where D* equals D/(D+S) and da/dn_{L} is the crack growth rate of a straight crack subjected to the same effective stress intensity. Therefore, the greater the crack deflection, i.e. large Θ, the smaller the crack propagation rate for the Mode I crack. This does not include the effect of the crack closure mismatch discussed above.

If the crack bifurcates, this blunts the crack tip region further and subjects the crack to an even lower apparent stress intensity factor for crack propagation.

Therefore, composite particles 10 and reinforcing particles 20 of sufficient size to create a large deflection in the material were selected for the inventive powder feedstock to reduce the apparent stress that the deflected crack would be seeing, and thereby slowing the propagation rate of the crack in the material. This effectively increases the fracture toughness of the material. The larger the composite particle 10, the larger the crack deflection angle and the slower the propagation rate given by Equation 1 above.

Cracks typically initiate from splat boundaries or porosity in the plasma sprayed coating and can quickly grow to thicknesses in excess of 1 micron. It is important, therefore, for the strengthening composite particles 10 to have sizes of about at least 2 microns (0.1 mils), or larger, more preferably about 5 microns (0.2 mils) or larger, and even more preferably about 10 microns (0.4 mils) or larger.

Hard refractory particles from at least the following list of aluminum diboride, titanium diboride, zirconium diboride, hafnium diboride, lanthanum hexaboride, rhenium diboride, strontium diboride, and others are ideal candidates for dispersoids (i.e. reinforcing particles 20) to increase the fracture toughness of ceramic topcoats in thermal barrier coatings. When added as loose powders in the feed stock of a plasma spray device, as mentioned above, the powders will lose some if not all of their mass due to thermal decomposition during spraying. The rare earth stabilized zirconia, titania, and hafnia coating materials of the powder feed stock, on the other hand, are stable in the plasma jet. One embodiment of the invention is to form a powder feed stock for the dispersion strengthened thermal barrier coatings consisting of ceramic coated strengthening particles (i.e. composite particles 10). The protective ceramic coating 30 protects the otherwise volatile boride and other strengthening reinforcing particles 20 therein from the plasma during plasma spraying. The size of the feed stock powder (i.e. composite particle 10) of about 10 microns (0.4 mils) to about 176 microns (7 mils), more preferably about 20 microns (0.8 mils) to about 90 microns (3.5 mils) and even more preferably about 55 microns (2.2 mils) to about 70 microns (2.8 mils), was chosen to ensure the melted zone of each composite particle 10 did not reach the strengthening reinforcing particle 20 therein during spraying.

To summarize, boride and other dispersed hard refractory reinforcing particles 20 in a plasma sprayed ceramic topcoat in a TBC, increase fracture toughness and resulting lifetime of the TBC. The inventive ceramic coated particle feedstock (i.e. which contains composite particles 10) discussed herein protects the volatile particles from the plasma during deposition and results in successful coating application.

Although the present invention has been described with reference to preferred embodiments, workers skilled in the art will recognize that changes may be made in form and detail without departing from the spirit and scope of the invention.

1. A method of forming a thermal barrier coating system on a turbine engine component, the method comprising: forming a bond coat on the turbine engine component; and forming a dispersion strengthened ceramic coating on the bond coat, wherein the dispersion strengthened ceramic coating comprises composite particles therein.

2. The method of claim 1, wherein the composite particles comprise reinforcing particles surrounded by a protective ceramic coating.

3. The method of claim 2, wherein the reinforcing particles comprise at least one of boride particles, carbide particles and oxynitride particles.

4. The method of claim 2, wherein the reinforcing particles comprise at least one of aluminum diboride, titanium diboride, tantalum diboride, zirconium diboride, hafnium diboride, lanthanum hexaboride, rhenium diboride, strontium diboride, tungsten diboride, silicon carbide, tantalum carbide, and silicon aluminum oxynitride.

5. The method of claim 2, wherein the reinforcing particles are about 2 microns (0.1 mils) to 40 microns (1.6 mils) in diameter.

6. The method of claim 2, wherein the composite particles are about 10 microns (0.4 mils) to 176 microns (7 mils) in diameter.

7. The method of claim 1, wherein the dispersion strengthened ceramic coating is formed by plasma spraying.

8. The method of claim 7, wherein the feedstock used for the plasma spraying comprises composite particles.

9. The method of claim 2, wherein the protective ceramic coating comprises at least one of yttria stabilized zirconia, rare earth stabilized zirconia, rare earth stabilized hafnia, and rare earth stabilized titanate.

10. The method of claim 1, wherein the bond coat comprises at least one aluminum containing alloy.

11. The method of claim 10, wherein the aluminum containing alloy comprises at least one of a nickel aluminide, a platinum modified nickel aluminide, and an MCrAlX material where M comprises at least one of iron (Fe), nickel (Ni), and cobalt (Co) and X comprises at least one of yttrium, (Y), silicon, (Si), hafnium (Hf), and a rare earth element.

12. A turbine engine component comprising:
a substrate;
a bond coat on the substrate; and
a dispersion strengthened ceramic coating on the bond coat, wherein the dispersion strengthened ceramic coating comprises composite particles therein.

13. The component of claim 12, wherein the composite particles comprise reinforcing particles surrounded by a protective ceramic coating.

14. The component of claim 13, wherein the reinforcing particles comprise at least one of boride particles, carbide particles, and oxynitride particles.

15. The component of claim 13, wherein the reinforcing particles comprise at least one of aluminum diboride, titanium diboride, tantalum diboride, zirconium diboride, hafnium diboride, lanthanum hexaboride, rhenium diboride, strontium diboride, tungsten diboride, silicon carbide, tantalum carbide, and silicon aluminum oxynitride.

16. The component of claim 13, wherein the reinforcing particles are about 2 microns (0.08 mils) to 40 microns (1.6 mils) in diameter.

17. The component of claim 13, wherein the composite particles are about 10 microns (0.4 mils) to 176 microns (7 mils) in diameter.

18. The component of claim 12, wherein the dispersion strengthened ceramic coating is formed by plasma spraying.

19. The component of claim 18, wherein the feedstock used for the plasma spraying comprises composite particles.

20. The component of claim 12, wherein the bond coat comprises at least one aluminum containing alloy.

21. The component of claim 20, wherein the aluminum containing alloy comprises at least one of a nickel aluminide, a platinum modified nickel aluminide, and an MCrAlX material comprises where M at least one of iron (Fe), nickel (Ni), and cobalt (Co), and X comprises at least one of yttrium (Y), silicon (Si), hafnium (Hf), and a rare earth element.

22. An improved plasma feed stock powder particle comprising reinforcing particles surrounded by a protective ceramic coating.

23. The reinforcing particle of claim 22, wherein the reinforcing particles comprise at least one of boride particles, carbide particles and oxynitride particles.

24. The powder particle of claim 22, wherein the protective ceramic coating comprises at least one of yttria stabilized zirconia, rare earth stabilized zirconia, rare earth stabilized hafnia and rare earth stabilized titanate.
